(19) United States
(12) Patent Application Publication
(10) Pub. No.: US 2009/0179262 A1
(43) Pub. Date: Jul. 16, 2009

(54) Floating Body Memory Cell with a Non-Overlapping Gate Electrode

(75) Inventors: Juergen Holz, Dresden (DE); Wolfgang Mueller, Radebeul (DE); Stefan Slesazeck, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/122,135

(22) Filed: May 16, 2008

Related U.S. Application Data
(60) Provisional application No. 61/021,488, filed on Jan. 16, 2008.

(51) Int. Cl. H01L 27/115; H01L 29/78

(52) U.S. Cl. 257/331; 257/E27.103

(57) ABSTRACT

An integrated circuit includes a memory cell with a transistor. The transistor includes first and second doped portions, and a third portion disposed between the first and second doped portions. The first and the second doped portions and the third portion are disposed in a semiconductor substrate. The transistor further includes a gate electrode adjacent to the third portion, the gate electrode being insulated from the third portion. The gate electrode does not overlap at least one of the first and second doped portions, and a line connecting the first and the second portions extends substantially perpendicular to a surface of the substrate.

### CROSS REFERENCE TO RELATED APPLICATIONS

This application claims priority under 35 U.S.C. 119(e) from U.S. Provisional Patent Application Ser. No. 61/021,488, filed Jan. 16, 2008, and entitled “Floating Body Memory Cell with a Non-Overlapping Gate Electrode,” the entire contents of which are hereby incorporated by reference.

### FIELD OF THE INVENTION

The present specification relates to a vertical floating body memory cell. Moreover, the present specification relates to transistors of such memory cells and a memory device comprising such memory cells and a special circuitry.

### BACKGROUND

Floating body memory cells usually employ charge storage effects in an insulated floating semiconductor body. The floating body may be disposed between two regions. A first region may be connected to a bit line and a second region may be connected to a source line. A gate electrode is configured to switch a current between the two regions by a select voltage applied to the gate electrode. By applying a suitable write signal to at least one of the terminals of the memory cell, a charge may be injected in or removed from the floating body. By applying a suitable read signal to at least one of the terminals, an output signal may be caused in the bit line. The output signal depends on the amount and/or type of charge stored in the floating body region. Usually, floating body memory cells need less space and, accordingly, may be arranged at a very dense pitch. Nevertheless, due to leakage currents, the retention time of these floating body memory cells can be problematic. Accordingly, there is a need for providing floating body memory cells having an improved retention time.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1A is a cross-sectional view of an array of transistors according to an implementation of the invention;

FIG. 1B is a perspective view of an array of transistors according to an implementation of the invention;

FIG. 2 shows a cross-sectional view of an array of transistors according to another implementation of the invention;

FIG. 3 shows a cross-sectional view of still a further implementation of the invention;

FIG. 4 shows a cross-sectional view of an array of transistors according to still another implementation of the invention;

FIG. 5 shows an equivalent circuit diagram of a memory device according to an implementation of the invention;

FIGS. 6A and 6B show schematic representations of memory cells according to an implementation of the present invention; and

FIGS. 7A to 7C show exemplary timing diagram of voltages when operating the memory device according to an implementation of the present invention.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top,” “bottom,” “front,” “back,” “leading,” “trailing,” “horizontal,” “vertical,” etc. is used with reference to the orientation of the figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

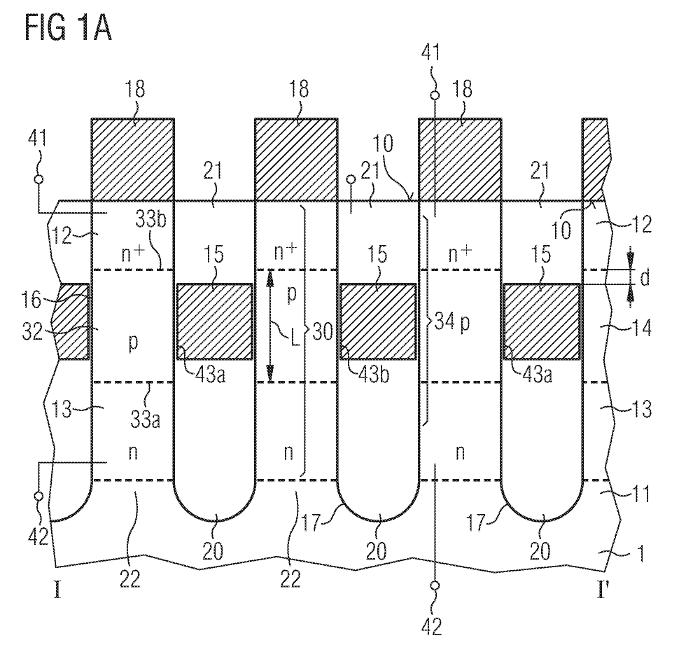

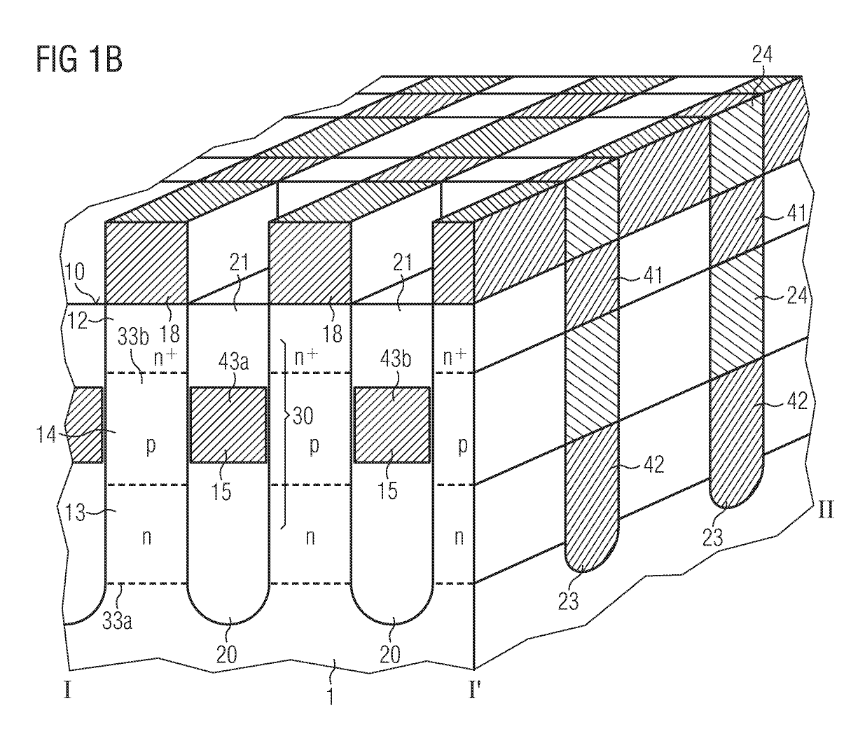

FIG. 1A shows a cross-sectional view of an integrated circuit according to an implementation of the present invention. The cross-sectional view shown in FIG. 1A is taken between I and I′ as can be gathered, for example, from FIG. 1B. The cross-sectional view shown in FIG. 1A is taken so as to intersect a plurality of single transistors 34. An integrated circuit comprises a memory cell 30, the memory cell including a transistor 34. As is shown in FIG. 1A, the transistor comprises a first doped portion 12 and second doped portion 13. The first and the second doped portions 12, 13 are disposed in a semiconductor substrate 1. The terms “wafer,” “substrate,” “semiconductor chip,” or “semiconductor substrate” used in the context of the present description may include any semiconductor-based structure that has a semiconductor substrate. Wafer and substrate are to be understood to include silicon, silicon-on-insulator (SOI), silicon-on-sapphire (SOS), doped and undoped semiconductors, epitaxial layers of silicon supported by a base crystalline material, and other semiconductor structures. The semiconductor need not be silicon-based. The semiconductor could as well be, among others, silicon-germanium, germanium or gallium arsenide. Various components may already be formed in the substrate. Moreover, different layers may be embedded in the substrate material.

The transistor further comprises a third portion 14. The third portion 14 is disposed between the first and second doped portions 12, 13. The first doped portion 12 adjoins the third portion 14 and a junction 33b, and the second doped portion 13 adjoins the third portion 14 at a junction 33a. The first and second doped portions 12, 13 as well as the third portion 14 are disposed in the semiconductor substrate 1 comprising a main surface 10. The transistor further comprises a gate electrode 15. The gate electrode 15 is adjacent to the third doped portion 14 and is insulated from the third portion 14 by a gate dielectric 16. The gate electrode 15 does not overlap at least one of the first and second doped portions 12, 13. Moreover, a line connecting the first and the second doped portions extends in the direction that is approximately vertical with respect to the main surface 10 of the substrate. In the context of the present specification, the term main surface 10 refers to an approximately horizontal surface. In other words, a line extending between the first and second doped portions 12, 13 is substantially perpendicular to the substrate surface, with the second doped portion 13 being below the first doped portion.

Accordingly, there may be a distance d between a boundary of the gate electrode 15 and either of the junctions 33a, 33b. In the context of the present specification the terms junctions and boundary refer to the metallurgical junction of the first or the second doped region and the third doped region. The junction is close to a portion of a vertical surface of the doped region, the vertical surface being adjacent to the gate electrode of the transistor 34. Moreover, the boundary of the gate electrode 15 refers to the portion of the boundary that is close to the substrate surface. The gate electrode may be arranged in such a manner that it does not overlap the whole length L of the channel of the transistor. For example, the length L of the channel may be less than 100 nm. By way of further example, the length L of the channel may be less than 75 nm and may be approximately 50 nm.

According to an implementation of the present invention, the gate electrode 15 may be disposed in a symmetric manner with respect to the first and second doped portions 12, 13. According to an alternative implementation, the gate electrode 15 may be disposed in an asymmetric manner with respect to the first and second doped portions 12, 13. For example, one of the first and second doped portions 12, 13 may overlap the gate electrode. As is further shown in FIG. 1A, the gate electrodes 15 may be disposed in grooves 17 that are arranged in the substrate. For example, the transistors 34 may be disposed in semiconductor material ridges 22 that are arranged between neighboring grooves 17. For example, the groove 17 may be filled with a bottom fill 20 that may be made of an insulating material such as silicon oxide, silicon nitride and others.

The gate electrodes 15 may be disposed over the bottom fill 20. Moreover, a top fill 21 which may be made of an insulating material that may be different or the same as the bottom fill is disposed over the gate electrodes 15. For example, segments of a cap layer 18 may be disposed over the first doped portions 12. The third portion 14 may be doped with a dopant having a conductivity type that is opposite to the conductivity type of the first and second doped portions, respectively. For example, the first and second doped portions 12, 13 may be n-doped, the third portion being p-doped, and vice versa. In the arrangement shown in FIG. 1A, the second doped portion 13 is disposed between the third portion 14 and the bulk semiconductor portion 11. Accordingly, there is no bulk contact between the third portion 14 and the bulk semiconductor portion 11. In the description, the terms “connect” and “couple” are intended to include a direct as well as an indirect “connect” and “couple,” respectively. Accordingly, components that are connected or coupled to each other may contact each other. Alternatively, these components may not contact each other, a third element being interposed between them.

The first doped region 12 may be connected with a bit line 41, and the second doped portion 13 may be connected with a source line 42. Moreover, the gate electrodes 15 may be connected with a corresponding word line 43a, 43b. Upon application of suitable potentials to the bit lines 41, optionally the source lines 42 as well as optionally the word lines 43a, 43b, the transistor may be operated in a bipolar mode with doped portion 12, 13 acting as collector and emitter respectively and portion 14 acting as base of the bipolar transistor. For example, holes may be generated by impact ionization at top junction 33b, acting as a base current and hence, giving rise to an electron current flow between emitter and collector. In such a condition, the transistor action is influenced by bipolar effects so that a control of the transistor action via the field effect is of minor importance. As a consequence, an overlap of the gate electrode over the whole channel length is not required. Due to the distance d between the gate electrode 15 and any of the first and second doped portions, a gate induced drain leakage is reduced. As a consequence, the retention time of the transistor may be improved.

FIG. 1B shows a perspective view of the integrated circuit shown in FIG. 1A. The left hand portion of FIG. 1B corresponds to the cross-sectional view shown in FIG. 1A. As is further shown in FIG. 1B, isolation trenches 23 are formed in a plane before and behind the plane of the drawing shown in FIG. 1A. For example, source lines and bit lines may be arranged in the isolation trenches 23. For example, in the bottom portion of the isolation trenches 23 source lines 42 may be disposed.

The source lines 42 may comprise a doped semiconductor material such as doped polysilicon or they may be made of another conductive material such as a metal. An insulating material 24 may be filled over the source line 42. In an upper portion of the isolation trenches 23, the bit lines 41 are disposed. The bit lines 41 may be made of a doped semiconductor material such as doped poly silicon or another conductive material such as a metal. On top of the bit lines 41, an arbitrary insulating 24 material may be disposed. In the arrangement shown in FIG. 1B, the source lines 42 as well as the bit lines 41 extend parallel to each other in a direction that is perpendicular to the direction of the word lines.

Nevertheless, as is clearly to be understood, any arbitrary arrangement of source lines, bit lines, and word lines may be chosen. As is usual, the word lines should extend in a direction that is perpendicular to the direction to the bit lines. Accordingly, a memory cell may be formed at a cross point between word line and bit line. The source lines may extend parallel to the word lines or parallel to the bit lines. As a further alternative, the source line may be implemented as a so-called buried plate, for example a doped portion that connects a plurality of second doped portions 13. As a further alternative, also the word line may be implemented as a plate. In the context of the present specification, the term “plate” or “buried plate” refers to any conductive structure or pattern by which a plurality of memory cells may be simultaneously addressed. Accordingly, this term encompasses any type of grid, plate including holes or array of lines that are held at one common potential. The plate or buried plate usually is disposed in the substrate.

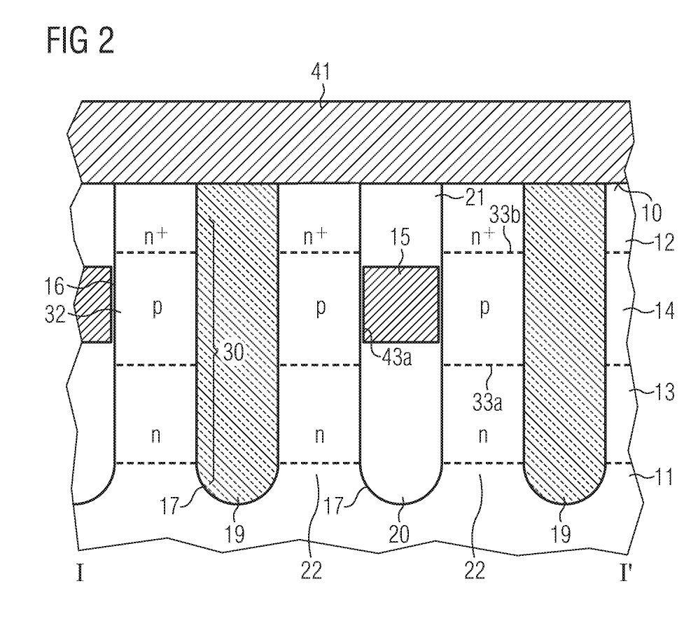

FIG. 2 shows a further implementation of the integrated circuit of the present invention. As is shown in FIG. 2, every second groove 17 is filled with an insulating material 19. Moreover, the bit line 41 is formed on top of the transistor array and patterned so as to extend in a direction that is perpendicular to the direction of the word line 43A. Nevertheless, as is clearly to be understood, the bit lines 41 may be implemented in any other manner. The remaining portions of FIG. 2 correspond to the respective elements shown in FIG. 1A.

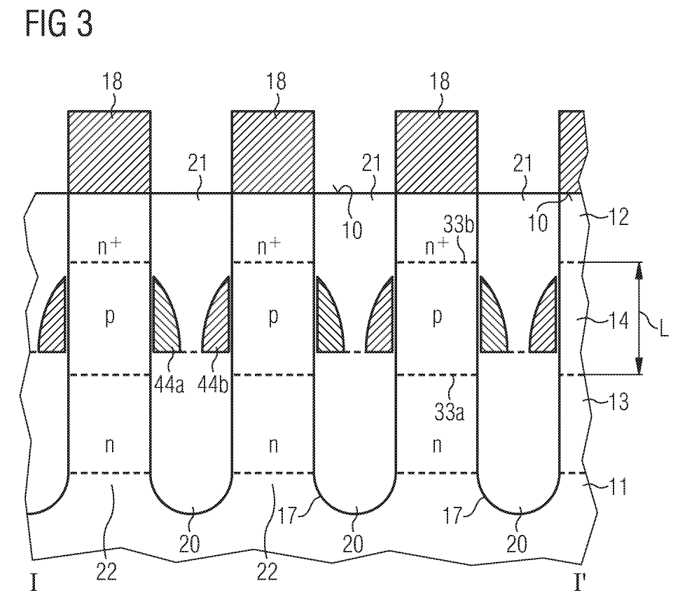

According to the implementation shown in FIG. 3, the word lines may be implemented as split word line 44a, 44b. For example, the word lines 44a, 44b may be formed by a spacer process when filling the conductive material into the grooves 17. Accordingly, for example, when manufacturing the word lines, first, a bottom fill 20 is filled into the grooves 17. Thereafter, a conformal conductive layer is deposited, followed by an anisotropic etching step. Accordingly, the horizontal portions of the conductive layer may be removed, leaving sidewall spacers adjacent to the sidewalls of the grooves. The upper portion of the spacers may be removed by a suitable etching method leaving the split word lines 44a, 44b as is shown in FIG. 3, for example. Thereafter, a top fill 21 may be formed over the word lines 44a, 44b. The remaining portions of the integrated circuit shown in FIG. 3 correspond to the respective portions of the integrated circuit shown in FIG. 1A. For example, before and behind the plane of the drawing shown in FIG. 3, two adjacent split wordlines, that are assigned to the same row of memory cells, may be merged.

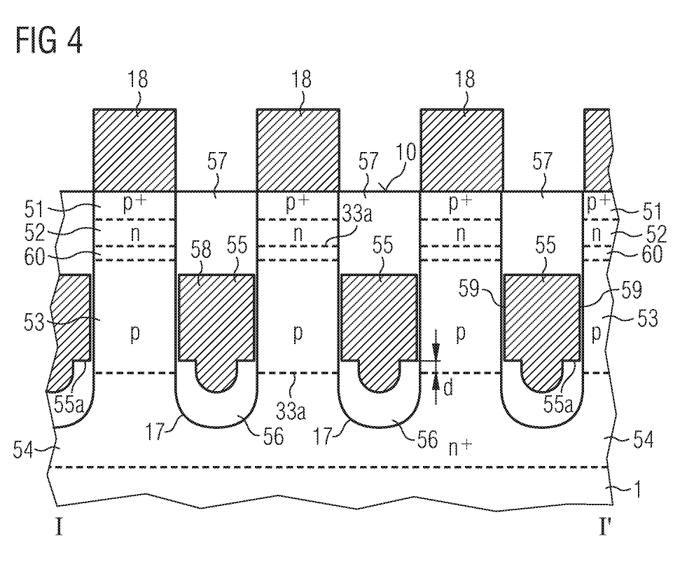

FIG. 4 shows still a further implementation of the integrated circuit according to the present invention. As is shown in FIG. 4, each of the memory cells comprises a thyristor comprising a first doped portion 52, a second doped portion 54 as well as third portion 53. The thyristor further comprises a fourth doped portion 51. The first and the second doped portions 52, 54 are doped with a dopant having a first conductivity type. The fourth doped portion 51 and the third portion 53 are doped with a dopant having a second conductivity type that opposite to the first conductivity type. Accordingly, as is shown in FIG. 4, a pnpn or an npnp-type arrangement is formed. For example, the fourth doped portion 51 may be p-doped and act as an anode and the second doped 54 may be n-doped and act as a cathode of the thyristor. A gate electrode 55 is disposed so as to be adjacent to the third portion 53. A floating body may be formed in the third portion 53.

The gate electrode 55 is formed so as not to overlap with at least one of the first and the second doped portions 52, 54. Moreover, an intrinsic portion 60 may be disposed between the first doped portion 52 and the third portion 53. For example, there may be an overlap between the intrinsic portion and a gate electrode 55 or not. As is shown in FIG. 4, there is a distance d between a lower boundary portion 55a of the gate electrode 55 close to an interface between gate dielectric and the third portion 53 and the junction 33a. The junction 33a is disposed between the second doped portion 54 and the third portion 53. Nevertheless, a lower portion of the gate electrode extends to a depth that lies beneath the junction 33a between the second doped portion 54 and the third portion 53. Due to the large thickness of the insulating material forming the bottom fill 56 of the grooves 17, the gate electrode is effectively shielded from the doped portion 54 so that this overlap does not cause a leakage current.

As is clearly to be understood, the basic concept underlying the structure shown in FIG. 4 may be modified in arbitrary manners. For example, any of the variations shown in FIGS. 2 and 3 may be combined with the thyristor structure shown in FIG. 4. Moreover, the structure shown in FIG. 4 may be rotated by 180° in a vertical direction. For example, the third doped portion 53 may be disposed over the first doped portion. Moreover, the gate electrode 55 may be disposed at a higher level than illustrated in FIG. 4. The word lines may be implemented as split word lines in a similar manner as is illustrated in FIG. 3. Moreover, before and behind the plane of the drawings, two adjacent split wordlines, that are assigned to the same row of memory cells, may be merged.

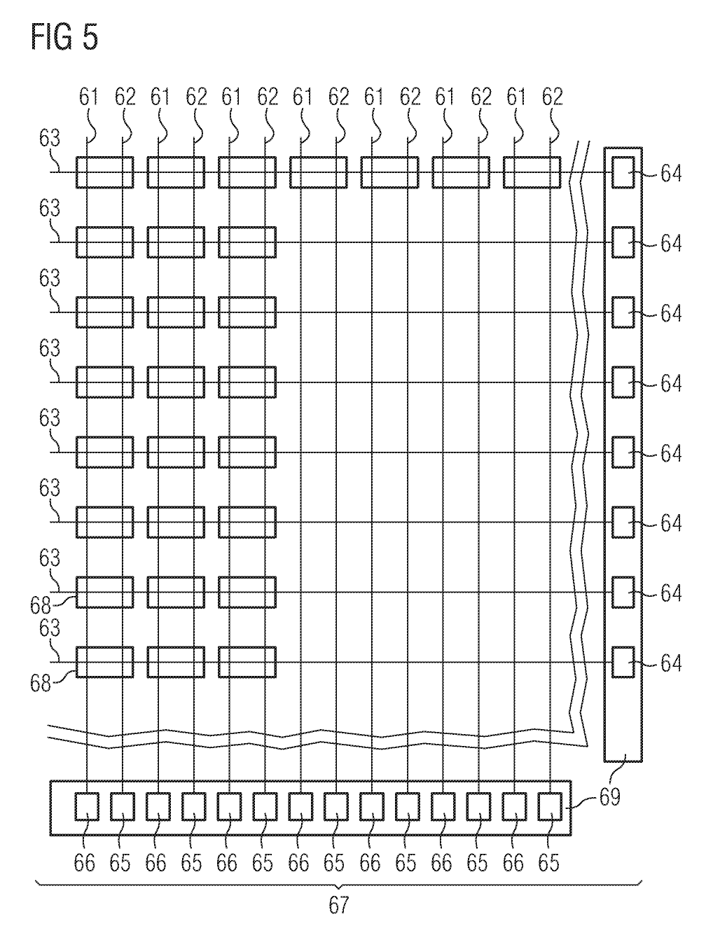

FIG. 5 shows an equivalent circuit diagram of a memory device comprising the transistor as shown in FIGS. 1 to 4, respectively. A memory device 67 comprises bit lines 61 and word lines 63. The bit lines 61 extend in a direction that is perpendicular to the direction of the word lines 63. Memory cells 68 are disposed at crossing points between word lines 63 and bit lines 61. The memory cells 68 are implemented in the manner as has been explained above. Moreover, source lines 62 may be disposed so as to be parallel with respect to the bit lines or they may be disposed parallel to the word lines 63.

In the arrangement shown in FIG. 5, the source lines 62 are implemented as lines that are parallel to the bit lines 61. According to an implementation, there may be an equal number of source lines and bit lines. For example, a source line may be connected with the second source/drain portion whereas the first source/drain portion of each of the memory cells 68 is connected with a bit line. According to another implementation, two rows of memory cells 68 may share one common source line. According to still a further implementation, the source line may be implemented as a buried plate that is connected with a plurality of memory cell columns. The memory device 67 may further comprise circuitry for correspondingly activating the word lines, the bit lines and, optionally, the source lines. For example, the circuitry 69 may comprise word line drivers 64 that are configured to correspondingly activate the word lines 63. Moreover, the circuitry 69 may comprise bit line drivers 66 that are configured to address the bit lines 61 and may sense the signal received from the bit lines 61. Additionally, the circuitry may also comprise source line drivers 65 that are configured to address the source lines 62 and may sense signals that are received from corresponding source lines 62.

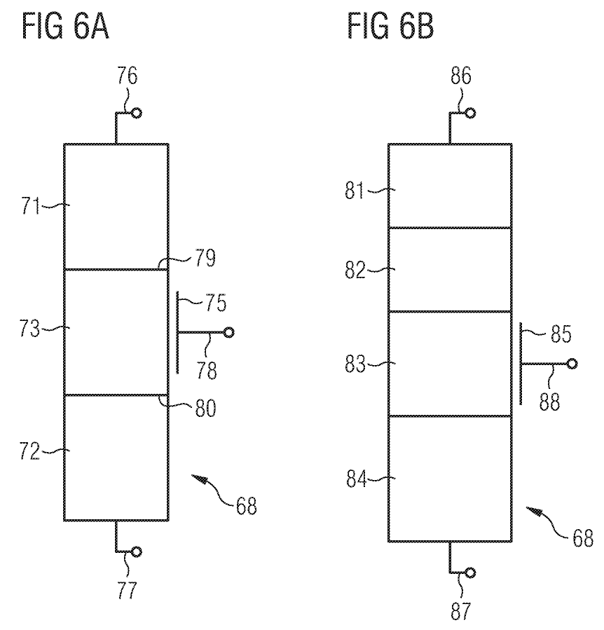

The memory cells 68 may be implemented in the manner as has been described above with reference to FIG. 1A, 1B to 3. Alternatively, the memory cells 68 may be configured in the manner as has been described with reference to FIG. 4. FIG. 6A shows a schematic representation of a memory cell that is depicted in FIGS. 1 to 3, respectively. The memory cell 68 that is shown in FIG. 6A may comprise a first and a second doped portion 71, 72 and a third doped portion 73 that is disposed between the first and the second doped portions, respectively. The first and second doped portions may be of a first conductivity type whereas the third doped portion is of a second conductivity type that is opposite to the first conductivity type. The first doped portion may be connected with a bit line and the second doped portion may be connected with a source line. Moreover, a gate electrode 75 is capacitively coupled to the third doped portion 73.

The gate electrode 75 may extend so that it does not reach the junction 79 between the first and the third doped portions, or so that it does not reach the second junction 80 between the second and third doped portions. As is clearly to be understood, the orientation shown in FIG. 6A as well as the assignment of doped portion to conductive line is arbitrary and can be implemented in any other manner as is generally known to the persons skilled in the art. The memory cell 68 stores information by means of a different charging state of the floating body that is disposed in the third doped portion 73. Generally, a logical “1” refers to a state in which majority carriers are stored in the third doped portion. In a logical state “0” approximately no majority carriers are stored in the third doped portion. According to a further implementation, different values may be stored in the transistor body portion for example by storing different amounts of charges.

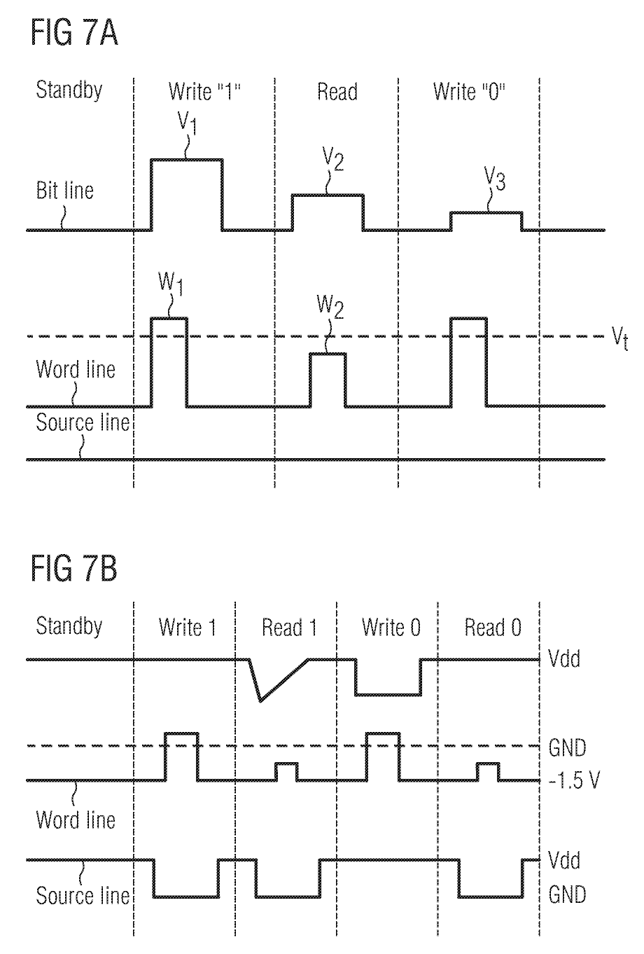

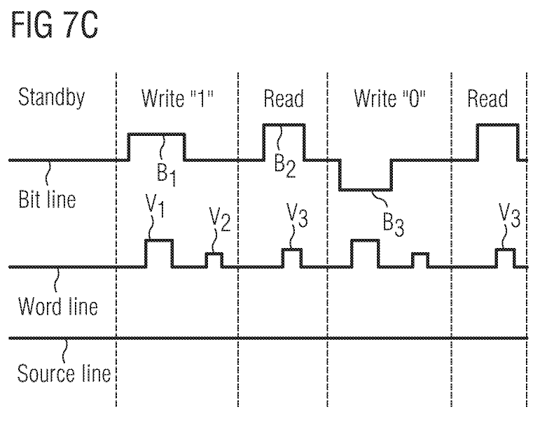

Usually, for reading the information that is stored in the memory cell 68, a voltage is applied between the first and second doped portions of the memory cell. Additionally, a suitable voltage pulse at the gate electrode is applied. Depending on the charging state of the floating body, accumulated holes are released from the gate-to-body capacitor and a current is generated. In this case, an ignition may be obtained. The memory cell 78 may be interpreted in terms of a bipolar transistor. Accordingly, in this case, reading and writing may be accomplished in a manner that is schematically depicted in FIG. 7A as an example.

In a standby mode the bit line, the word line, and the source line may be held at a reference voltage level. For writing a “1,” a voltage V1 may be applied to the bit line while holding a source line at a reference level. Moreover, a voltage W1 that is higher than the threshold voltage is applied to the gate electrode, inducing an electron current flowing between the first and the second doped portion. Due to the high voltage that is applied between the first and the second doped portions, impact ionization takes place at the first junction 79, causing a hole current to flow from the junction 79 towards the second doped region 72, acting as a base current for the intrinsic bipolar transistor formed from the three doped regions. In the case that impact ionization rate and bipolar current gain are high enough, the ignited bipolar current becomes approximately independent of the voltage that is supplied to the gate electrode. The voltage that is supplied to the gate electrode is decreased to a hold voltage below the threshold voltage of the transistor while the body potential remains at a high level. For example, the hold voltage may be equal to the reference voltage. Thereafter, the voltage that is applied to the bit line is set to the reference value. For performing a read operation, a voltage V2 is applied to the bit line. The voltage V2 may be selected in such a manner that it does not cause a punch-through but it is high enough so as to cause an impact ionization to take place at the first junction 79. The voltage V2 may be equal to the voltage V1. Moreover, for initializing the transistor action, a voltage pulse is needed at the gate electrode. Accordingly, after applying a voltage V2 to the bit line, a voltage W2 is applied to the gate electrode that is lower than the threshold voltage and lower than W1 of the transistor. After applying this voltage pulse, an ignition of the bipolar current may be caused in case a “1” is stored in the transistor body, whereas no ignition is caused in case a “0” is stored in the transistor body. For writing a “0,” majority carriers have to be removed from the transistor body 73. Accordingly, a voltage V3 is applied between the bit line and the source line, V3 being not suitable to cause an impact ionization at the first junction 79. For example, V3 may be 0 V or at a low level or V3 may be negative with respect to the source line. Moreover, a gate voltage is applied to the gate electrode, the gate voltage being higher than the threshold voltage of the transistor. Accordingly, the body to source diode becomes forward biased in order to remove carriers from the transistor body 73. The signal that is applied to the wordline may be equal to the signal for writing a “1.” After setting the voltage of the bit line to the reference value, the gate voltage is set to the hold voltage, i.e., the voltage that is needed to hold the signal. As has been shown in this example, the circuitry 69 shown in FIG. 5 may be implemented in such a manner, that the source lines are held at a reference value. Moreover, the bit line drivers 66 may be implemented in such a manner so that different voltage values may be applied, and that a current flowing may be detected. Moreover, the word line drivers 64 may be implemented in such a manner, that several different types of voltage-timings may be applied to the word lines depending from whether a reading, writing “0” or writing “1” operation is performed. For example, for reading and writing a “0” or a “1,” a gate voltage may be changed.

As a further example, the memory cell 68 may be implemented in the manner as has been described above with reference to FIG. 4. FIG. 6B shows an equivalent representation of such a memory cell 68. As is shown, this memory cell may comprise a pnpn or npnp-doped semiconductor structure. An intrinsic portion may be disposed between the first and third doped portions 82, 83. The fourth doped portion 81 may be connected with the bit line 86 and the second doped portion 84 may be connected with the source line 87. Moreover, the gate electrode 85 may be connected with the word line 88. In the arrangement shown in FIG. 6B, the memory cell 68 is implemented via a so-called thyristor that may be represented by two bipolar transistors, each of them “sharing” the base diffusions with the collector diffusion of the other transistor respectively. In the memory cell 68 that is shown in FIG. 6B, the information is stored via majority carriers that are stored in the third doped portion or floating body 83. Depending on the charge state of the floating body or third doped portion, the thyristor may be ignited or not when a voltage is applied between the fourth and second doped portions 81, 84. For example, a current flow may be initialized by applying a suitable voltage between the fourth and the second doped portions. Accordingly, no impact ionization may be necessary in order to provide a current flow. As a consequence, usually the voltages which are applied between the bit line 86 and the source line 87 are lower. As a consequence, leakage currents are reduced, thus improving the retention time of the resulting memory cell.

Examples of timing diagrams of voltages that are applied to the bit line, the word line and the source line are shown in FIG. 7B. As is shown, the wordline, the bitline, and the source line may be addressed for performing a desired memory cell action. Reading and writing may be accomplished by activating corresponding bit lines and word lines while leaving the source lines at a reference potential. In this case, the circuitry of the memory device is implemented in such a manner that corresponding signals are given to the bit line for writing a logical “0” or a logical “1.” For example, a voltage B1 may be applied for writing a “1,” and a voltage B3 may be applied for writing a “0.” For example, B3 may be zero or at a low value or B3 may be even negative with respect to the source line. Moreover, a corresponding signal B2 is given to the bit line for reading. For example, B2 may be equal to B1. In addition, the word line receives corresponding signals for writing and for reading. For example, the word line receives a first voltage pulse V1 and, after finishing the writing operation, a second voltage V2. Thereby, the charging state of the transistor body is lowered so that upon application of a voltage to the bit line, no current flow is caused. Nevertheless, for reading the information, a voltage V3 is applied to the gate electrode in order to ignite the thyristor. According to this implementation, the write operation comprises a step of partially removing the charge stored in the transistor body. Moreover, the reading operation comprises a step of applying a gate voltage.

Nevertheless, as is clearly to be understood, these timing diagrams are given by way of example only and there may be many modifications and variations in which the memory device 67 shown in FIG. 5 may be operated.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit, comprising:
a transistor comprising:
first and second doped portions;
a third portion disposed between the first and second doped portions, the first and second doped portions and the third portion being disposed in a semiconductor substrate; and
a gate electrode adjacent to the third portion, the gate electrode being insulated from the third portion;
wherein the gate electrode does not overlap at least one of the first and second doped portions and a line connecting the first and the second portions extends in a direction substantially perpendicular to a surface of the substrate.

2. The integrated circuit of claim 1, wherein:
the transistor is one of a plurality of transistors of the integrated circuit; and
the gate electrodes of respective transistors are disposed in grooves arranged in the substrate, the transistors being disposed in ridges that are disposed between neighboring grooves.

3. The integrated circuit of claim 2, wherein two gate electrodes are disposed in one groove, the two gate electrodes being adjacent to respective sidewalls of the one groove, wherein the gate electrodes in the one groove are insulated from each other.

4. The integrated circuit of claim 2, wherein the gate electrodes are disposed in every second groove, every other second groove being filled with an insulating material.

5. The integrated circuit of claim 1, wherein the third portion is doped with a dopant having a conductivity type that is opposite to the conductivity type of the first and second doped portions, respectively.

6. The integrated circuit of claim 1, wherein the third portion is not doped.

7. The integrated circuit of claim 1, further comprising a fourth doped portion that is adjacent to the first doped portion on a side opposite to the third portion.

8. The integrated circuit of claim 7, further comprising an intrinsic portion that is disposed between the first doped portion and the third portion, the intrinsic portion being substantially non-doped.

9. The integrated circuit of claim 1, further comprising a bulk semiconductor portion, wherein the third portion is isolated from the bulk semiconductor portion by the second doped portion.

10. The integrated circuit of claim 1, wherein the integrated circuit comprises a memory cell and the third portion defines a storage node in which information is stored.

11. An integrated circuit, comprising:
a memory device comprising:
bit lines;
word lines; and
storage transistors, each of the storage transistors comprising:
first and second doped portions;
a third portion disposed between the first and second doped portions, the first and second doped portions and the third portion being disposed in a semiconductor substrate; and
a gate electrode adjacent to the third portion, the gate electrode being insulated from the third portion,
wherein the gate electrode does not overlap at least one of the first and second doped portions and the third portion extends in a direction substantially perpendicular to a surface of the substrate.

12. The integrated circuit of claim 11, wherein:
the storage transistor is one of a plurality of storage transistors of the memory device; and
the gate electrodes of respective storage transistors are disposed in grooves that are arranged in the substrate, the transistors being disposed in ridges that are disposed between neighboring grooves.

13. The integrated circuit of claim 12, wherein two gate electrodes are disposed in one groove, the two gate electrodes being adjacent to respective sidewalls of the one groove, wherein the gate electrodes in the one groove are insulated from each other.

14. The integrated circuit of claim 12, wherein the gate electrodes are disposed in every second groove, every other second groove being filled with an insulating material.

15. The integrated circuit of claim 12, wherein the bit lines are in signal connection with the first doped portions of respective storage transistors and the gate electrodes of respective storage transistors are in signal connection with the word lines,
the integrated circuit further comprising circuitry configured to apply first voltage signals to the bit lines and second voltage signals to the word lines.

16. The integrated circuit of claim 15, further comprising source lines that are in signal connection with the second doped portions of respective storage transistors, the source lines being maintained at a reference voltage.

17. The integrated circuit of claim 12, wherein the bit lines are in signal connection with the first doped portions of respective storage transistors and the gate electrodes of respective storage transistors are in signal connection with the word lines,
the integrated circuit further comprising circuitry configured to apply first voltage signals to the bit lines and second voltage signals to the word lines.

18. The integrated circuit of claim 17, further comprising source lines that are in signal connection with the second doped portions of respective storage transistors, the source lines being maintained at a reference voltage.

19. The integrated circuit of claim 11, further comprising a fourth doped portion that is adjacent to the first doped portion on a side opposite to the third portion.

20. The integrated circuit of claim 11, further comprising an intrinsic portion that is disposed between the first doped portion and the third portion, the intrinsic portion being substantially non-doped.

21. The integrated circuit of claim 11, wherein the semiconductor substrate comprises a bulk portion, and the third portion is isolated from the bulk portion by the second doped portion.

22. The integrated circuit of claim 11, wherein the third portion defines a storage node in which information is stored.

23. The integrated circuit of claim 11, wherein the first doped portion defines a storage node in which information is stored.
